(19) United States
(12) Patent Application Publication
(10) Pub. No.: US 2004/0183135 A1
(43) Pub. Date: Sep. 23, 2004

(54) ESD dissipative structural components

(76) Inventors: Oh-Hun Kwon, Westboro, MA (US); Matthew A. Simpson, Sudbury, MA (US)

Correspondence Address: TOLER & LARSON & ABEL L.L.P., 5000 PLAZA ON THE LAKE STE 265, AUSTIN, TX, 78746, US

(21) Appl. No.: 10/391,989

(22) Filed: Mar. 19, 2003

(51) Int. Cl. H01L 23/62

(52) U.S. Cl. 257/355

(57) ABSTRACT

A structural component is provided that includes a substrate and a ceramic layer deposited thereon. The ceramic layer is formed of a ceramic electrostatic discharge dissipative material and has an electrical resistivity within a range of about 10³ to about 10¹¹ ohm-cm.

### BACKGROUND

1. Field of the Invention

The present invention is generally related to structural components, and in particular, structural components having electrostatic discharge dissipative properties for safe discharge of electrostatic charges.

2. Description of the Related Art

In the context of microelectronic manufacturing, sensitive microelectronic devices are typically handled by automated means and/or people in environments such as a cleanroom. In this context, handling and manufacturing operations tend to generate a buildup of static electricity, also known as triboelectric charges. In the context of a cleanroom environment for manufacturing microelectronic devices, such as integrated circuits through wafer processing operations, buildup of electrostatic charges tends to cause contamination issues. In particular, charged surfaces within the cleanroom environment tend to attract and hold contaminants, making removal of particles in the cleanroom difficult. Beyond the existence of electrostatic charges causing contamination issues, discharge of electrostatic charges tends to cause additional problems. For example, many microelectronic devices such as integrated circuits, analog devices, storage media and storage devices, can be damaged, by the uncontrolled discharge of static electricity can damage electrical circuitry. In the case of catastrophic damage, such damage may be detected during testing phases at the back-end of the manufacturing process. However, perhaps even more problematic, electrostatic discharge can cause latent defects which then surface during later stage integration by customers, or during use of the microelectronic device as incorporated in an electronic component by an end user.

Background information on this subject provided by the Electrostatic Discharge Association, found at www.esda.org, details various approaches for dealing with electrostatic charges. While one methodology of addressing problems associated with electrostatic discharge calls for the reduction and, if possible, elimination of electrostatic buildup, it is difficult to completely eliminate generation of all static electricity in a given environment. Accordingly, steps have been taken to safely dissipate or neutralize electrostatic charges as they are formed. In this regard, to prevent damage of a sensitive microelectronic device, it has typically been sought to control the rate of discharge by using an electrostatic discharge (ESD) dissipative material. In this regard, certain process tooling used in the fabrication process have been formed of suitable polymers, as polymers can readily be formed into any needed geometric shape, and the resistivity of polymers can be controlled over a fairly wide range. However, mechanical properties of polymers are poor. For example, most polymer materials are not abrasion resistant, creep under loading, and have an elastic modulus which is less than 10 GPa.

Coatings on polymers have also been used in the art. In one example, a vanadium pentoxide sol is applied together with a binder on a surface, leaving a “fibrous or ribbon-like network” of vanadium oxide particles bonded by a polymeric binder. Such coatings can be applied to most kinds of surfaces. However, such coatings lack wear resistance and are unsuitable for long-term service in areas where frequent contact with parts might occur, such as bench tops. In a clean-room environment the fibers are susceptible to separating from the surface, which leads to contamination.

In an effort to address some of the shortcomings of polymer materials, electrostatic discharge dissipative ceramic materials have been developed. One example is disclosed in U.S. Pat. No. 6,274,524, which describes formation of a ceramic material formed of zirconium oxide and iron oxide. However, the disclosed material, as with many ceramic materials, is expensive to make in large size pieces, such as monolithic handling tools, furniture and fixtures.

Accordingly, in view of the foregoing, it is considered generally desirable to provide improved electrostatic discharge dissipative materials, components, and methods for forming such materials and components, such as for use in a microelectronic fabrication environment.

### BRIEF DESCRIPTION OF THE DRAWINGS

The present invention may be better understood, and its numerous objects, features, and advantages made apparent to those skilled in the art by referencing the accompanying drawings.

FIG. 1 is a vacuum chuck according to an embodiment of the present invention.

### The use of the same reference symbols in different drawings indicates similar or identical items.

### SUMMARY

According to one aspect of the present invention, a structural component is provided that includes a substrate and a ceramic layer deposited thereon. The ceramic layer is formed of a ceramic electrostatic discharge dissipative material and has an electrical resistivity within a range of about 10³ to about 10¹¹ ohm-cm. The component may have an electrical resistivity within a slightly narrower range, such as within a range of 10⁵ to about 10⁹ ohm-cm, for particular applications. The ceramic layer may be deposited by thin or thick-film forming techniques. In one embodiment, the ceramic layer is deposited by a thick-film forming technique known as thermal spraying. The structural component may be configured for use in connection with microelectronic handling, such as microelectronic device manufacturing operations.

### DESCRIPTION OF THE PREFERRED EMBODIMENT(S)

According to an embodiment of the present invention, a structural component is provided that includes a substrate and a ceramic layer deposited on the substrate. The ceramic layer is formed of an electrostatic discharge dissipative material which has an electrical resistivity within a range of about 10³ to about 10¹¹ ohm-cm. The foregoing resistivity measurement denotes volume resistivity.

The actual resistivity of a given embodiment is chosen based on a number of factors. Considerations include the resistance of the discharge path to ground, which is dependent on coating resistivity and the thickness of the coating. Thus if the coating is to be very thin (as might be the case if structural features on the coated part were very fine, or it the part itself were very small), then one would choose a higher resistivity within the above range for the coating than if the coating were several millimeters thick. Generally, resistances to ground in the range 10⁵-10⁹ ohms are preferred, as this tends to keep stray currents less than one milliamp with typical electrostatic voltages of less than 1000V, while at the same time allowing charge to dissipate in less than a few seconds.

The actual configuration and intended deployment of the structural component may vary. For example, the structural component may be used in an environment in which microelectronic devices are handled, such as in a manufacturing environment. Typical microelectronic devices that are handled in environments sensitive to electrostatic buildup and/or discharge include integrated circuit devices formed by wafer processing techniques (e.g., MOS devices), storage media and storage devices (e.g., hard disk drives, optical drives, and magnetic and optical media), read/write heads for magnetic storage media, CCD arrays, analog devices (e.g., RF transistors), optoelectronics (e.g., waveguides and related components), acoustoelectrical devices (e.g., SAW filters), photomasks, and micro-electro-mechanical systems (MEMS).

The structural component may be a piece of furniture utilized in a handling environment, such as a fabrication environment for microelectronic devices. Such furniture pieces may be broadly characterized in several different categories, including storage furniture, transport furniture for transporting microelectronic devices, and support devices, which provide a working surface for receiving microelectronic devices for processing operations, for example. In addition, such furniture may include a physical floor, such as floor tiles. Examples of storage component furniture pieces include shelving, racks, cabinets, and drawers. Examples of transport components for handling and transporting microelectronic devices include carts, trays, wafer carriers, robot end effectors, conveyors, and conveying rollers. One example of a wafer carrier which is emerging into more common use is the so-called front opening unified pod (FOUP). Examples of furniture piece that are support components include workbenches and worksurfaces.

In the particular case of fabrication environments, such as a wafer fab, horizontal surfaces of the furniture pieces are typically engineered to maintain laminar flow within the cleanroom environment. To this end, vertical surfaces are typically engineered so as to have a fairly high degree of open area, as opposed to solid work surfaces, for example. The open area may be greater than 50% of the entire horizontal surface area of the particular furniture piece, such as greater than about 60%, or even 70%. The working surface having such an open area may be formed by parallel rods or bars, or grid-like arrays of rods or bars, or may be a perforated surface.

In addition to furniture pieces, the particular form of the structural component may be a microelectronic fixture, which is configured to receive single or multiple microelectronic devices. For example, in the case of a semiconductor fabrication environment, multiple fixtures are used within processing tools for holding wafers in a single-wafer processing operation or multi-wafer processing operations. Such processing operations may include, for example, oxide formation, deposition, metallization, lithography, etching, ion implantation, heat treatment, ion milling, polishing (including chemical-mechanical polishing), wet cleaning, metrology, test, and packaging. The form of the fixture may include diffusion, photolithographic, deposition, metallization, etching, polishing, machining, and lapping fixtures. Likewise, the furniture described above may be used in connection with any of the foregoing processing operations. A particular example of a fixture is a jig used in single wafer processing operations such as deposition (e.g., chemical vapor deposition) and etching operations, or fixtures for disposition in an ultrasonic tank for workpiece processing. Typically the structural component is limited to passive components, which are not designed to be connected to a power source, and which lack electrodes, contacts, interconnects, etc.

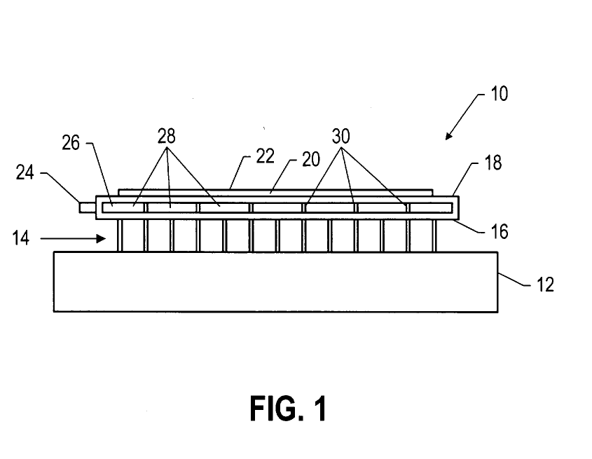

Turning to FIG. 1, an embodiment of the present invention is shown, in particular, a vacuum chuck for flat panel display (FPD) processing. In this example, the vacuum chuck 10 includes a base 12 and a deformable mounting plate 16 which is connected to the base 12 through a plurality of actuators 14. The actuators may be electrical transducers, for example, that are effective to physically bias and control the contour of the mounting plate 16. The mounting plate 16 receives and holds a substrate 20 via vacuum, the substrate in this case being a FPD component, such as a sheet of transparent plastic or glass. The vacuum is created by attaching a vacuum source to vacuum port 24, and evacuating chamber 26, which is divided into a plurality of regions 28 defined between walls 30. By controlling the actuators 14 by a controller (not shown), the contour of the mounting plate may be manipulated such that the top surface 22 of the substrate 20 is adjusted to be relatively planar. By doing so, the substrate can be adjusted to be relatively flat, which is desirable for later processing operations, such as laminating additional layers with the substrate 20. Additional details of the vacuum chuck and operation thereof are shown in U.S. Pat. No. 5,724,121, details of which are incorporated herein.

The mounting plate 16 may be formed of a suitable ceramic or metal alloy material. It is coated with a ceramic layer in accordance with the teachings herein. The ceramic layer is disposed on at least a top surface 18 (receiving surface for receiving the substrate) of the mounting plate 16, and, as described above, is formed of an electrostatic discharge dissipative material Generally, after forming the ESD dissipative ceramic layer, it is lapped and polished to achieve desired surface flatness, texture and roughness. Additional features of the ceramic layer are described herein. By incorporating such an ESD dissipative material, the static charges can be safely neutralized before causing damage to the substrate or sensitive electrical devices such as the actuators, and before causing process control issues such as alignment problems or contamination. In addition, chucking and de-chucking operations and cycle time are improved.

Further, the particular configuration of the structural component may be as a tool used in handling or fabrication of microelectronic devices. One example includes wire-bonding tips used in a wire bonding packaging operation of integrated circuit die. Others include tweezers, which are commonly used for manual handling of microelectronic devices, pick and place tips used for handling of IC chips in packaging and testing, and dispensing nozzles for adhesives and processing liquids used in contact with ESD sensitive IC chips and other devices.

Use of the substrate/ceramic layer bi-component structure permits use of a wide range of materials, including materials that are relatively inexpensive for formation of the substrate. Accordingly, a wide range of substrate materials may be utilized, including materials which otherwise would not be utilized in sensitive electrostatic discharge environments. Such materials include metals, including metal alloys. For example, the foregoing furniture pieces, fixtures and tools may be formed of an aluminum or iron alloy, including carbon steels, tool steels, stainless steels, etc. In some instances it may be possible to apply a dense ceramic coating even on a polymeric substrate.

Turning to the ceramic layer, the ceramic layer is generally deposited on the substrate. In this regard, the ceramic layer is generally a coating, which falls into a broader category generally understood in the art as surface treatments. Surface treatments include not only coatings, or treatments which cover a surface of the substrate, but also treatments which alter surfaces of a substrate (e.g., hardening operations, high energy treatments, thin diffusion treatments, heavy diffusion treatments, and other treatments such as cryo, magnetic and sonic treatments). For applications within cleanroom environments, it is very desirable that the coating does not shed particles during service. Accordingly, the coating is typically at least 85% of theoretical density, such as at least about 90% of theoretical density. A light polishing step to the coating may also be beneficial in limiting the tendency to shed particles.

In the area of coatings or surface coverings, general categories include conversion coatings, electroplating, electroless plating, hardfacing, thermal spraying and thin-film coating. Conversion coating generally refers to chemical conversion along an exposed surface of the substrate, such as formation of oxide coatings (including by anodization, which is formed by a forced electrolytic oxidation of the aluminum surface), phosphate coatings and chromate coatings. Electroless plating, also known as autocatalytic plating, as well as electroplating are both understood in the art and not described in detail herein, and electroless plating is generally not used according to embodiments of the present invention. Thin-film coatings generally involve a deposition of a material atom-by-atom or molecule-by-molecule, or by ion deposition onto a solid substrate. Thin-film coatings generally denote coatings having a nominal thickness less than about 1 micron, and most typically fall within fairly broad categories of physical vapor deposition coatings (PVD coatings), and chemical vapor deposition coatings (CVD coatings), and atomic layer deposition (ALD).

According to embodiments of the present invention, the coating is deposited rather than formed via a conversion technique, and generally by one of a thin film and a thick film technique so as to be limited to depositional coatings. Use of such depositional films is superior to conversion surface layers such as anodization. While anodized aluminum layers have been utilized in the past in an attempt to provide a static-dissipative barrier between a surface and an aluminum metal substrate, their conductivity depends critically on the residual porosity of the surface and the humidity of the environment in which they operate. Accordingly, it is difficult to control their properties sufficiently to create a surface resistance to ground in the range required to dissipate static electricity effectively. In addition, anodized layers tend to lack certain mechanical properties, such as sufficient abrasion resistance

Particular embodiments take advantage of thick film deposition, such as by a thermal spraying process. Thermal spraying includes flame spraying, plasma arc spraying, electric arc spraying, detonation gun spraying, and high velocity oxy/fuel spraying. Particular embodiments have been formed by depositing the layer utilizing a flame spray technique, and in particular, a flame spray technique utilizing the Rokide® process, which utilizes a Rokide® flame spraying spray unit. In this particular process, a ceramic material formed into the shape of a rod is fed into a Rokide® spray unit at a constant and controlled feed rate. The ceramic rods are melted within the spray unit by contact with a flame that is generated from oxygen and acetylene sources, atomized, and sprayed at a high velocity (such as on the order of 170 m/s) onto the substrate surface. The particular composition of the ceramic rod is chosen for superior electrostatic discharge dissipative properties, discussed in more detail below. The oxyacetylene flame generates a processing temperature on the order of 2760° C. According to the process, fully molten particles are sprayed onto the surface of the substrate, and the spray unit is configured such that particles are not projected from the spray unit until being fully molten. The kinetic energy and high thermal mass of the particles maintain the molten state until reaching the substrate.

The foregoing thermal spraying processes fall within the category of thick-film forming processes, wherein the resulting layer has a thickness greater then about 1 micron. Embodiments of the present invention have a thickness that is effective to provide adequate surface coverage and mechanical properties such as abrasion resistance, as used in the intended environment. Embodiments may have thickness greater than about 10 microns, such as greater than about 20 microns, or even 50 microns. The thickness of the coatings may extend into the millimeter range, such as 2-3 millimeters.

The ceramic layer may be monocrystalline, polycrystalline, a combination of polycrystalline and amorphous (crystalline and glassy phases), or amorphous (typically monocrystalline is not used according to embodiments of the present invention). The ceramic layer, and in particular the base material of the ceramic layer, may have multiple phases or a single phase. Use of the term ‘ceramic layer’ herein generally means that the principal component or components, totaling at least 50 wt %, is/are ceramic components. Typically, the ceramic layer contains at least 60, 70, 80, or at least 90 wt % ceramic. The ceramic layer is generally free of binders and organic processing aids. Generally, the ceramic layer is formed by a high temperature process with burns out binders and any processing aids. Indeed, in certain coating techniques, such as by thermal spraying discussed in more detail below, no binders/processing aids are used for executing coating.

The ceramic layer may be formed of an oxide, nitride or carbide-based composition, or combinations thereof. As used herein, description of a ‘base’ composition generally refers to a base material that accounts for at least 50 weight percent of the ceramic layer, typically greater then 60 weight percent, such as greater then 70 or 80 weight percent. By way of example, the ceramic layer may be formed of a base composition that is a densified product from aluminum oxide, chromium oxide, nickel oxide, cobalt oxide, manganese oxide, copper oxide, vanadium oxide, yttrium oxide, silicon oxide, iron oxide, titanium oxide, zirconium oxide, silicon nitride, aluminum nitride, silicon carbide and compounds and combinations thereof. The foregoing description of a densified product from the list of materials generally denotes that the layer is a densified material of a particular feedstock material. For example, the feedstock material may be a ceramic composition having multiple phases, such as aluminum oxide and yttrium oxide combined, which may form a single phase or multi phase material in its coating form by the high temperature deposition process such as flame spraying. For example, yttrium oxide and aluminum oxide may form one of or a combination of garnet, monoclinic and perovskite yttria-alumina crystal phases. The foregoing description of materials accordingly refers to the feedstock material(s).

According to another embodiment of the present invention, the ceramic layer is formed of an oxide-based composition. In this regard, oxide-based compositions are particularly desirable when utilizing a thermal spray technique, such as flame spraying. The oxide-based composition may have a base composition that is a densified product from aluminum oxide, chromium oxide, yttrium oxide, titanium oxide, zirconium oxide, silicon oxide, and combinations thereof.

In particular embodiments it is desirable to incorporate an additive in the base composition for reducing a resistivity of the ceramic layer, such as in the case of the base material having too high of a resistivity for adequate dissipation of electrostatic charges. The additive is typically formed of a conductive or semi-conductive discrete particulate phase, which forms a distinct second phase within the base composition, which may be a single phase.

The following table provides various combinations of base materials and resistivity modifier additives. Note that different combinations may have different efficacy. For example ZnO is a particularly effective additive for zirconia-based materials, but may not exhibit the same degree of behavior with other base materials such as alumina.

| Base material | Semi-conductor | | Resistivity modifier |
|---|---|---|---|
| (Insulator) | type | General Formula | (Examples) |
| Zirconia | Carbide | MC | B₄C, SiC, TiC, Cr₄C, VC, ZrC, |
| | | | TaC, WC, graphite, carbon |
| Y-TZP | Nitride | MN | TiN, ZrN, HfN, |
| Ce-TZP | Boride | MB | TiB₂, ZrB₂, CaB₆, LaB₆, NbB₂, |
| Mg-PSZ | Silicide | MSi | MoSi₂, |
| | Carbonitride | M(C, N) | Ti(C, N), Si(CN), |
| | Single oxide | MO | NiO, FeO, MnO, Co₂O₃, Cr₂O₃, |
| | | | Fe₂O₃, Ga₂O₃, In₂O₃, GeO₂, |
| | | | MnO₂, TiO₂₋ₓ, RuO₂, Rh₂O₃, |
| | | | V₂O₃, Nb₂O₅, Ta₂O₅, WO₃, |
| | Doped oxide | (M + m)O | SnO₂, ZnO, CeO₂, TiO₂, ITO, |
| | Perovskite | ABO₃ (AO.BO₂) | MgTiO₃, CaTiO₃, BaTiO₃, |
| | | | SrTiO₃, LaCrO₃, LaFeO₃, |
| | | | LaMnO₃, YMnO₃, MgTiO₃F, |
| | | | FeTiO₃, SrSnO₃, CaSnO₃, |
| | | | LiNbO₃, |
| | Spinel¹ | AB₂O₄ (MO.Fe₂O₃) | Fe₃O₄, MgFe₂O₄, MnFe₂O₄, |
| | | | CoFe₂O₄, NiFe₂O₄ ZnFe₂O₄, |
| | | | CoFe₂O₄, CoFe₂O₄, FeAl₂O₄, |
| | | | MnAl₂O₄, ZnAl₂O₄, ZnLa₂O₄, |
| | | | FeAl₂O₄, MgIn₂O₄, MnIn₂O₄, |
| | | | FeCr₂O₄, NiCr₂O₄, ZnGa₂O₄, |
| | | | LaTaO₄, NdTaO₄, |
| | Magnetoplumbite | MO.6Fe₂O₃ | BaFe₁₂O₁₉, |
| | Garnet | 3M₂O₃.5Fe₂O₃ | 3Y₂O₃.5Fe₂O₃ |
| ZTA | Other oxides | | Bi₂Ru₂O₇, |
| Alumina | | | TiO₂₋ₓ, |
| SiC | | | Si₃N₄ bonded |
| Silicon nitride | | | SiC, TiN, |
| SiAION | | | TiN, Ti(O, N) |
| Aluminum nitride | | | TiN, |

According to embodiments of the present invention, methods for using the structural component are provided. According to one embodiment, a method of handling a microelectronic device calls for providing a structural component comprising a substrate and a ceramic layer deposited thereon, the ceramic layer comprising a ceramic electrostatic discharge dissipative material and having an electrical resistivity within a range of about 10³ to about 10¹¹ ohm-cm; and placing the microelectronic device on the structural component. The microelectronic device need not be placed directly on and contact the structural component, but may have an intervening element or elements between the structural component or components. The component may be a furniture piece as described above, such a furniture piece for storage, for a processing operation wherein the furniture piece has a working surface (e.g., a workbench), or for transport. In addition, the structural component may be a fixture which is configured to directly contact the microelectronic device for a processing operation, or a tool for executing a processing operation.

### EXAMPLES

### Example 1

A support plate approximately 2 cm² and having a thickness of 0.3 cm was fabricated from a piece of carbon steel. The Rokide® thermal spray process was utilized to form a chromium-oxide layer having a thickness of 500 microns. The electrical resistance between the sprayed face and the substrate was measured in a number of places, and it was found to be on the order of 3 to 5×10⁶ ohms, providing desirable resistance for dissipation of electrostatic charges.

### Example 2

Following the same process of example 1, high purity alumina (greater then 98% pure alumina) and titania (TiO₂) were combined at a ratio of 87 weight percent and 13 weight percent, respectively. The resistivity of the material was found to be about 2.8×10⁸ ohm-cm.

What is claimed is:

1. A structural component, comprising:
a substrate; and
a ceramic layer deposited thereon, said ceramic layer comprising a ceramic electrostatic discharge dissipative material and having an electrical resistivity within a range of about 10³ to about 10¹¹ ohm-cm.

2. The structural component of claim 1, wherein the electrical resistivity of the ceramic electrostatic discharge dissipative material is within a range of about 10⁵ to about 10⁹ ohm-cm.

3. The structural component of claim 1, wherein the substrate is metal or a metal alloy.

4. The structural component of claim 3, wherein the substrate comprises an aluminum alloy or an iron alloy.

5. The structural component of claim 4, wherein the substrate comprises steel.

6. The structural component of claim 1, wherein the layer has a thickness greater than about 1 μm.

7. The structural component of claim 1, wherein the layer has a thickness greater than about 10 μm.

8. The structural component of claim 1, wherein the layer has a thickness greater than about 20 μm.

9. The structural component of claim 1, wherein the layer has a thickness greater than about 50 μm.

10. The structural component of claim 1, wherein the structural component is a furniture piece for disposition in a microelectronic fabrication environment.

11. The structural component of claim 10, wherein the furniture piece is a storage component for storing microelectronic devices, the storage component being selected from a group consisting of shelving, racks, cabinets, and drawers.

12. The structural component of claim 10, wherein the furniture piece is a transport component for handling and transporting microelectronic devices, the transport component being selected from a group consisting of carts, trays, and wafer carriers, robot end effectors, conveyors, conveying rollers.

13. The structural component of claim 12, wherein the transport component comprises a wafer carrier, said wafer carrier being a front opening unified pod (FOUP).

14. The structural component of claim 1, wherein the structural component comprises a workbench.

15. The structural component of claim 1, wherein the structural component comprises a fixture for receiving a microelectronic component.

16. The structural component of claim 15, wherein the fixture is selected from the group consisting of diffusion, photolithographic, deposition, metallization, etching, polishing, machining, and lapping fixtures.

17. The structural component of claim 1, wherein the structural component comprises a floor covering for provision in a microelectronic fabrication environment.

18. The structural component of claim 1, wherein the structural component comprises a tool for handling microelectronic devices.

19. The structural component of claim 18, wherein the tool is configured to handle semiconductor devices.

20. The structural component of claim 18, wherein the tool is selected from the group consisting of wire bonding tips, tweezers, pick and place tips, and dispensing.

21. The structural component of claim 1, wherein the ceramic layer comprises a thermally sprayed thick film coating.

22. The structural component of claim 21, wherein the ceramic layer is deposited by a thermal spray technique selected from the group consisting of flame spraying, plasma arc spraying, electric arc spraying, detonation gun spraying, and high-velocity oxy-fuel spraying.

23. The structural component of claim 22, wherein the ceramic layer is deposited by flame spraying.

24. The structural component of claim 21, wherein the ceramic layer comprises an oxide-based composition.

25. The structural component of claim 24, wherein the ceramic layer is formed of a base composition that is a densified product from aluminum oxide, chromium oxide, yttrium oxide, titanium oxide, zirconium oxide, silicon oxide, nickel oxide, cobalt oxide, manganese oxide, copper oxide, vanadium oxide, and combinations thereof.

26. The structural component of claim 1, wherein the ceramic layer comprises an oxide, nitride, or carbide-based composition.

27. The structural component of claim 26, wherein the ceramic layer is formed of a base composition that is a densified product from aluminum oxide, chromium oxide, silicon oxide, iron oxide, nickel oxide, cobalt oxide, manganese oxide, copper oxide, vanadium oxide, yttrium oxide, titanium oxide, zirconium oxide, silicon nitride, aluminum nitride, silicon carbide, and combinations and compounds thereof.

28. The structural component of claim 1, wherein the ceramic layer comprises an additive provided in a base composition for reducing a resistivity of the layer.

29. The structural component of claim 28, wherein the additive comprises a semi-conductive or a conductive discrete particulate phase.

30. A method of handling a microelectronic device, comprising:
providing a structural component comprising a substrate and a ceramic layer deposited thereon, said ceramic layer comprising a ceramic electrostatic discharge dissipative material and having an electrical resistivity within a range of about 10³ to about 10¹¹ ohm-cm; and
placing the microelectronic device on the structural component.

31. The method of claim, wherein the structural component comprises a fixture.

32. The method of claim, wherein the structural component comprises a furniture piece.

33. A method of fabricating a microelectronic device, comprising:
providing a floor in a microelectronic fabrication environment comprising a substrate and a ceramic layer deposited thereon, said ceramic layer comprising a ceramic electrostatic discharge dissipative material and having an electrical resistivity within a range of about 10³ to about 10¹¹ ohm-cm; and
exposing the microelectronic device to a processing operation in the microelectronic fabrication environment.

34. A method of fabricating a microelectronic device, comprising:
providing a tool comprising a substrate and a ceramic layer deposited thereon, said ceramic layer comprising a ceramic electrostatic discharge dissipative material and having an electrical resistivity within a range of about 10³ to about 10¹¹ ohm-cm; and
exposing the microelectronic device to the tool to execute a processing operation.
